(19) United States
(12) Patent Application Publication
(10) Pub. No.: US 2025/0357093 A1
(43) Pub. Date: Nov. 20, 2025

(54) SUBSTRATE PROCESSING DEVICE INCLUDING VARIABLE IMPEDANCE ELEMENT

(71) Applicant: SAMSUNG ELECTRONICS CO., LTD., Suwon-si (KR)

(72) Inventors: Nam Kyun KIM, Suwon-si (KR); HADONG JIN, Suwon-si (KR); DONGHYEON NA, Suwon-si (KR); WOONGJIN CHEON, Suwon-si (KR); KYUNG-SUN KIM, Suwon-si (KR); SUNGYONG LIM, Suwon-si (KR)

(73) Assignee: SAMSUNG ELECTRONICS CO., LTD., Suwon-si (KR)

(21) Appl. No.: 19/016,854

(22) Filed: Jan. 10, 2025

(30) Foreign Application Priority Data
May 20, 2024 (KR) 10-2024-0065276

(51) Int. Cl. H01J 37/32

(52) U.S. Cl. CPC H01J 37/32715; H01J 37/32541; H01J 37/32642; H01J 2237/2007

(57) ABSTRACT

A substrate processing device is provided. The substrate processing device includes: a chamber body; an electrostatic chuck provided in the chamber body, the electrostatic chuck including a plasma electrode and a first chuck electrode; a first power source configured to supply alternating current power to the plasma electrode; a second power source configured to generate variable direct current power; a variable impedance circuit configured to provide a first electrical signal to the first chuck electrode based on the variable direct current power; and a controller connected with the second power source and the variable impedance circuit. The controller is configured to variably adjust a first impedance value of the variable impedance circuit with respect to the first chuck electrode and a magnitude of the variable direct current power to control a plurality of harmonic waves formed over the electrostatic chuck by the alternating current power.

### CROSS-REFERENCE TO RELATED APPLICATION

This application claims priority under 35 U.S.C. § 119 to Korean Patent Application No. 10-2024-0065276, filed on May 20, 2024, in the Korean Intellectual Property Office, the disclosure of which is incorporated by reference herein in its entirety.

### BACKGROUND

One or more example embodiments relate to a substrate processing device, and more particularly, relate to a substrate processing device including a variable impedance element.

Alternating current power having various frequencies may be supplied to a substrate processing device to control the generation of plasma. More specifically, a plasma concentration or a plasma sheath shape on a central portion or an edge portion of a substrate may be controlled by the alternating current power. In addition, direct current power may be supplied to the substrate processing device to fix the substrate.

However, because a harmonic wave is formed over the substrate due to the alternating current power, it is difficult to uniformly control the plasma concentration on the substrate.

### SUMMARY

One or more example embodiments provide a substrate processing device including a variable impedance element.

According to an aspect of an example embodiment, a substrate processing device includes: a chamber body; an electrostatic chuck provided in the chamber body, the electrostatic chuck including a plasma electrode and a first chuck electrode provided over the plasma electrode; a first power source configured to supply alternating current power to the plasma electrode; a second power source configured to generate variable direct current power; a variable impedance circuit configured to provide a first electrical signal to the first chuck electrode based on the variable direct current power; and a controller connected with the second power source and the variable impedance circuit. The controller is configured to variably adjust any one or any combination of a first impedance value of the variable impedance circuit with respect to the first chuck electrode and a magnitude of the variable direct current power to control a plurality of harmonic waves formed over the electrostatic chuck by the alternating current power.

According to another aspect of an example embodiment, a substrate processing device includes: a chamber body; an electrostatic chuck provided in the chamber body, the electrostatic chuck including a plasma electrode, a first chuck electrode provided over the plasma electrode and a second chuck electrode adjacent the first chuck electrode; a first power source configured to supply alternating current power to the plasma electrode; a second power source configured to generate variable direct current power; a variable impedance circuit configured to, based on the variable direct current power, provide a first electrical signal to the first chuck electrode and a second electrical signal to the second chuck electrode; and a controller connected with the second power source and the variable impedance circuit. The controller is configured to variably adjust a magnitude of the variable direct current power and a ratio between a first impedance value of the variable impedance circuit with respect to the first chuck electrode and a second impedance value of the variable impedance circuit with respect to the second chuck electrode to control a plurality of harmonic waves formed over the electrostatic chuck by the alternating current power.

According to another aspect of an example embodiment, a substrate processing device includes: a chamber body; an electrostatic chuck provided in the chamber body, the electrostatic chuck including a plasma electrode, a first chuck electrode provided over the plasma electrode, a second chuck electrode surrounding the first chuck electrode and a third chuck electrode surrounding the second chuck electrode; a first power source configured to supply alternating current power to the plasma electrode; a second power source configured to generate variable direct current power; a variable impedance circuit configured to provide a first electrical signal, a second electrical signal, and a third electrical signal to the first chuck electrode, the second chuck electrode and the third chuck electrode, respectively, based on the variable direct current power; and a controller connected with the second power source and the variable impedance circuit. The controller is configured to variably adjust a first impedance value of the variable impedance circuit with respect to the first chuck electrode, a second impedance value of the variable impedance circuit with respect to the second chuck electrode, a third impedance value of the variable impedance circuit with respect to the third chuck electrode, and a magnitude of the variable direct current power to control a plurality of harmonic waves formed over the electrostatic chuck by the alternating current power.

### BRIEF DESCRIPTION OF THE FIGURES

The above and other aspects and features will be more apparent from the following description of example embodiments, taken in conjunction with the accompanying drawings, in which:

FIG. 1 is a view illustrating a substrate processing device according to an example embodiment;

FIG. 2 is an enlarged sectional view illustrating a portion of a processing chamber according to an example embodiment;

FIG. 3 is a view illustrating a variable impedance element and a second power source connected to a chuck electrode according to some example embodiments;

FIG. 4 is a graph depicting reflection coefficients versus harmonic numbers according to some example embodiments;

FIG. 5 is a graph depicting a plasma concentration on a substrate depending on the distance from the center of the substrate according to some example embodiments;

FIG. 6 is a view illustrating a chuck electrode divided into two chuck electrodes according to some example embodiments;

FIG. 7 is a view illustrating a substrate processing device including a chuck electrode according to an example embodiment;

FIG. 8 is a view illustrating a second power source and a variable impedance element according to an example embodiment;

FIG. 9 is a view illustrating a substrate processing device including a chuck electrode according to an example embodiment;

FIG. 10 is a view illustrating a chuck electrode divided into three chuck electrodes according to some example embodiments; and

FIG. 11 is a view illustrating substrate processing device including a chuck electrode according to an example embodiment.

### DETAILED DESCRIPTION

Hereinafter, example embodiments will be described clearly and in detail to such an extent that those skilled in the art easily implement the present disclosure. Throughout the specification, like reference numerals may refer to like components. In addition, hereinafter, a first direction D1 may indicate any direction, a second direction D2 may indicate a direction crossing the first direction D1, and a third direction D3 may indicate a direction crossing the first direction D1 and the second direction D2. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one from among,” and “at least one of,” when preceding a list of elements, modify the entire list of elements and do not modify the individual elements of the list. For example, the expression, “at least one from among a, b, and c,” should be understood as including only a, only b, only c, both a and b, both a and c, both b and c, or all of a, b, and c. Embodiments described herein are example embodiments, and thus, the present disclosure is not limited thereto, and may be realized in various other forms. Each example embodiment provided in the following description is not excluded from being associated with one or more features of another example or another embodiment also provided herein or not provided herein but consistent with the present disclosure.

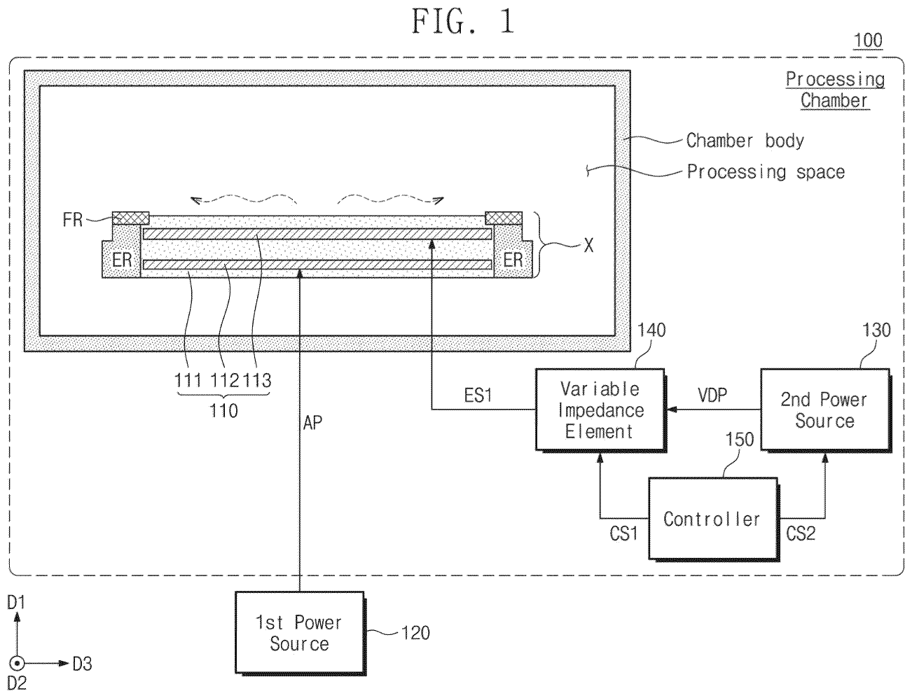

FIG. 1 is a view illustrating a substrate processing device 100 according to an example embodiment. Referring to FIG. 1, the substrate processing device 100 may include a first power source 120 and a processing chamber.

The first power source 120 may provide alternating current power AP to the processing chamber. The frequency of the alternating current power AP may be a first frequency. The substrate processing device may further include alternating current power sources that generate alternating current powers having various frequencies. For example, the first power source 120 may produce the alternating current power AP having a frequency of 58 MHz to 62 MHz. More specifically, the first power source 120 may produce the alternating current power AP having a frequency of 60 MHz. The frequencies of the alternating current powers supplied by the other alternating current power sources may range from 390 kHz to 410 kHz, or may range from 8 MHz to 10 MHz. More specifically, the frequencies may be 400 kHz and 9 MHz. However, example embodiments are not limited thereto, and the first power source 120 may supply the alternating current powers having the various frequencies described above to the processing chamber. The alternating current powers may be referred to as radio frequency (RF) powers.

The processing chamber may perform an etching process and a deposition process on a substrate. The term “substrate” used herein may refer to a silicon (Si) wafer. However, example embodiments are not limited thereto. The processing chamber may use plasma in the etching process and the deposition process. The processing chamber may generate and control the plasma in various ways. Specifically, the processing chamber may be capacitively coupled plasma (CCP) or inductively coupled plasma (ICP) equipment. Hereinafter, for convenience of description, it will be exemplified that the processing chamber is CCP equipment. However, example embodiments are not limited thereto.

The processing chamber may include a chamber body, an electrostatic chuck 110, a second power source 130, a variable impedance element (i.e., variable impedance circuit) 140, and a controller 150. The processing chamber may further include a showerhead, an outer ring, a heating liner ring, a vacuum pump, a gas supply device, a heater, a cooling plate, and the like. For example, the showerhead may be located in the chamber body and may be vertically spaced apart from the electrostatic chuck 110. A gas supplied by the gas supply device may be uniformly injected into a processing space through the showerhead. The outer ring may surround the showerhead. That is, the outer ring may surround the showerhead on the outside of the showerhead when viewed from above the plane. The heating liner ring may surround the outer ring and may support the outer ring. The heating liner ring may include aluminum (Al) and yttrium oxide (Y₂O₃). More specifically, the heating liner ring may have a form in which aluminum (Al) is coated with yttrium oxide (Y₂O₃).

The chamber body may provide the processing space. Processes may be performed on the substrate in the processing space. The processing space may be separated from the outer space. In some example embodiments, the processing space may be in a substantially vacuum state while the processes are performed on the substrate. The chamber body may have a cylindrical shape. However, example embodiments are not limited thereto.

The electrostatic chuck 110 may fix the substrate at a specific position in the processing space. More specifically, the substrate may be fixed to the upper surface of the electrostatic chuck 110. An edge ring ER may surround the electrostatic chuck 110. The edge ring ER may support a focus ring FR. The edge ring ER may include an edge electrode. Plasma on the edge portion of the substrate may be precisely controlled by the focus ring FR.

Specifically, the electrostatic chuck 110 may include a chuck body 111, a plasma electrode 112, and a chuck electrode 113.

The chuck body 111 may have a cylindrical shape. The chuck body 111 may include ceramic. However, example embodiments are not limited thereto. For example, the substrate may be disposed on the upper surface of the chuck body 111.

The plasma electrode 112 may be provided in the chuck body 111. The plasma electrode 112 may include aluminum (Al). The plasma electrode 112 may have a disk shape, but is not limited thereto. The plasma electrode 112 may receive the alternating current power AP from the first power source 120. The plasma electrode 112 may be surrounded by the edge electrode in the edge ring ER and may be electrically connected with the edge electrode. Plasma in the processing space may be controlled by the alternating current power SP supplied to the plasma electrode 112.

The chuck electrode 113 may be provided in the chuck body 111 and may be located over the plasma electrode 112. The chuck electrode 113 may receive a first electrical signal ES1 from the second power source 130. The first electrical signal ES1 may correspond to variable direct current power VDP transmitted through variable impedance element 140. The first electrical signal ES1 may or may not be the same as the variable direct current power VDP and may vary depending on the design of the variable impedance element 140. The substrate may be fixed to a specific position on the chuck body 111 by the first electrical signal ES1 corresponding to the variable direct current power supplied to the chuck electrode 113. The chuck electrode 113 may include aluminum (Al). However, example embodiments are not limited thereto.

The second power source 130 may generate the variable direct current power VDP. The variable direct current power VDP may represent direct current power whose magnitude (or, voltage) varies under the control of the controller 150. For example, the second power source 130 may vary the magnitude of the variable direct current power VDP based on a second control signal CS2 received from the controller 150. The second power source 130 may provide the variable direct current power VDP to the variable impedance element 140.

The variable impedance element 140 may provide the first electrical signal ES1 to the chuck electrode 113 based on the variable direct current power VDP. More specifically, the variable direct current power VDP may be supplied to the chuck electrode 113 through the variable impedance element 140, and the impedance value of the variable impedance element 140 with respect to the chuck electrode 113 may vary depending on the structure of the variable impedance element 140. For example, the impedance value of the variable impedance element 140 with respect to the chuck electrode 113 may indicate the impedance value viewed from the chuck electrode 113 toward the variable impedance element 140.

In some example embodiments, the variable impedance element 140 may include any one or any combination of an inductor, a variable capacitor, and the like.

For example, the variable impedance element 140 may include at least one variable capacitor. More specifically, the variable capacitor may include a vacuum variable capacitor (VVC). However, example embodiments are not limited thereto. The capacitance value of the variable capacitor may be changed under the control of the controller 150.

The variable impedance element 140 may receive a first control signal CS1 from the controller 150. The impedance value of the variable impedance element 140 with respect to the chuck electrode 113 may be controlled according to the first control signal CS1 of the controller 150. For example, the variable capacitor in the variable impedance element 140 may change the capacitance by changing the distance between two electrodes based on the first control signal CS1.

In some example embodiments, the variable impedance element 140 may be connected to the chuck electrode 113 and the second power source 130.

In some example embodiments, the variable impedance element 140 may be connected between the chuck electrode 113 and the second power source 130.

The controller 150 may be connected with the second power source 130 and the variable impedance element 140. The controller 150 may generate the first control signal CS1 and the second control signal CS2. The controller 150 may provide the first control signal CS1 and the second control signal CS2 to the variable impedance element 140 and the second power source 130, respectively.

In this regard, the controller 150 may adjust the magnitude of the variable direct current power VDP generated by the second power source 130 and the impedance value of the variable impedance element 140.

In some example embodiments, the controller 150 may generate the first control signal CS1 and the second control signal CS2 based on preset values. The preset values may indicate the magnitude of the variable direct current power VDP and the impedance value previously set based on the design of the variable impedance element 140, the frequency of the alternating current power, and the length of the substrate.

For example, the preset values may be obtained through experimental data when designing the substrate processing device 100, or may be obtained through machine learning based on the experimental data.

In some example embodiments, the controller 150 may obtain information about a plasma concentration distribution formed in the processing space in real time and may generate the first control signal CS1 and the second control signal CS2 based on the obtained information. For example, when a change in plasma concentration due to a harmonic wave is sensed on the substrate in the processing space, the controller 150 may generate the first control signal CS1 and the second control signal CS2 to control the harmonic wave to reduce the change in plasma concentration.

In a related substrate processing device, a plurality of harmonic waves are generated over a substrate by alternating current power supplied to a processing chamber. The harmonic waves may have frequencies that are integer multiples of a fundamental frequency. A harmonic wave having a frequency that is N times greater than the fundamental frequency may be referred to as an Nth harmonic wave. In this case, N is a natural number.

For example, a first frequency of a first harmonic wave among the plurality of harmonic waves may be equal to the frequency of the alternating current power. A second frequency of a second harmonic wave among the plurality of harmonic waves may be twice the frequency of the alternating current power. A third frequency of a third harmonic wave among the plurality of harmonic waves may be three times greater than the frequency of the alternating current power.

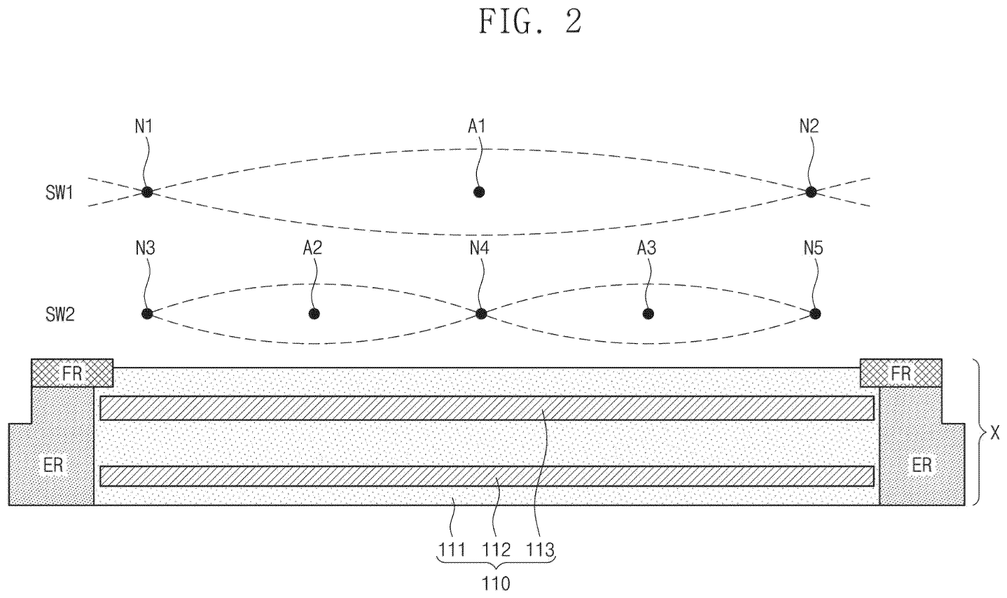

A harmonic wave due to the alternating current power may be generated at the center of the substrate and may be reflected at the edge portion of the substrate. More specifically, the harmonic wave may be reflected at the edge portion of the substrate due to an impedance difference at the edge portion of the substrate. A reflected wave generated by the reflection of the harmonic wave may be transmitted to the central portion of the substrate. At this time, a standing wave may be formed over the substrate (or, the electrostatic chuck 110) by the harmonic wave and the reflected wave. The numbers of anti-nodes and nodes of the standing wave formed over the substrate may vary depending on the length of the substrate and the frequency of the harmonic wave. A more detailed description thereof will be given below with reference to FIG. 2.

The plurality of harmonic waves, the reflected wave, and the standing wave described above may affect plasma in the processing chamber. Specifically, a plasma concentration may be different from a designed plasma concentration. For example, the plasma concentration may not be uniformly maintained.

In some example embodiments, the controller 150 may adjust the magnitude of the variable direct current power VDP and the impedance value of the variable impedance element 140 to control a plurality of harmonic waves formed over the electrostatic chuck 110.

In some example embodiments, the controller 150 may adjust the magnitude of the variable direct current power VDP and the impedance value of the variable impedance element 140 to remove (or, reduce) at least one harmonic wave among the plurality of harmonic waves. For example, the removed (or, reduced) harmonic wave may be a harmonic wave that most affects the plasma concentration on the substrate. In another example, the removed (or, reduced) harmonic wave may be a harmonic wave rather than the first harmonic wave.

In some example embodiments, the controller 150 may remove (or, reduce) the above-described reflected wave by adjusting the impedance value of the variable impedance element 140 or the magnitude of the variable direct current power VDP such that the impedance value of the variable impedance element 140 with respect to the chuck electrode 113 is equal to the impedance value of the variable impedance element 140 with respect to the edge ring ER or the focus ring FR (that is, an impedance difference does not occur at the edge portion of the substrate).

FIG. 2 is an enlarged sectional view illustrating a portion X of the processing chamber of FIG. 1. Referring to FIG. 2, the electrostatic chuck 110, the edge ring ER, and the focus ring FR are illustrated. In addition, standing waves SW1 and SW2 formed by alternating current power in the related substrate processing device are illustrated over the electrostatic chuck 110 of FIG. 2. The electrostatic chuck 110, the edge ring ER, and the focus ring FR of FIG. 2 correspond to the electrostatic chuck 110, the edge ring ER, and the focus ring FR of FIG. 1, respectively.

The chuck body 111, the plasma electrode 112, and the chuck electrode 113 of the electrostatic chuck 110 correspond to the chuck body 111, the plasma electrode 112, and the chuck electrode 113 of FIG. 1, respectively.

The standing waves SW1 and SW2 appearing in the related substrate processing device may vary depending on the diameter of the substrate (or, the electrostatic chuck 110) and the frequency of the alternating current power (or, the frequency of a harmonic wave).

The first standing wave SW1 may represent a standing wave that has two nodes N1 and N2 and one anti-node A1 over the electrostatic chuck 110. For example, the first anti-node A1 of the first standing wave SW1 may be located over the central portion of the electrostatic chuck 110. The first node N1 and the second node N2 of the first standing wave SW1 may be located close to the edge portion of the substrate.

The second standing wave SW2 may represent a standing wave that has three nodes N3, N4, and N5 and two anti-nodes A2 and A3 over the electrostatic chuck 110. For example, the fourth node A4 of the second standing wave SW2 may be located over the central portion of the electrostatic chuck 110. The second anti-node A2 and the third anti-node A3 may be located at the next-closest portion to the central portion of the electrostatic chuck 110. The third node N3 and the fifth node N5 may be located over the edge portion of the electrostatic chuck 110.

Although only the first standing wave SW1 and the second standing wave SW2 are illustrated for convenience of description, the position of a standing wave, the number of anti-nodes, and the number of nodes are not limited thereto, and various types of standing waves may be formed over the electrostatic chuck 110.

In the related substrate processing device, a plasma concentration different from the designed plasma concentration may be formed in the processing chamber by the standing waves SW1 and SW2. In particular, there is a tendency for a large difference in plasma concentration to occur at the positions corresponding to the anti-nodes and the nodes of the standing waves SW1 and SW2.

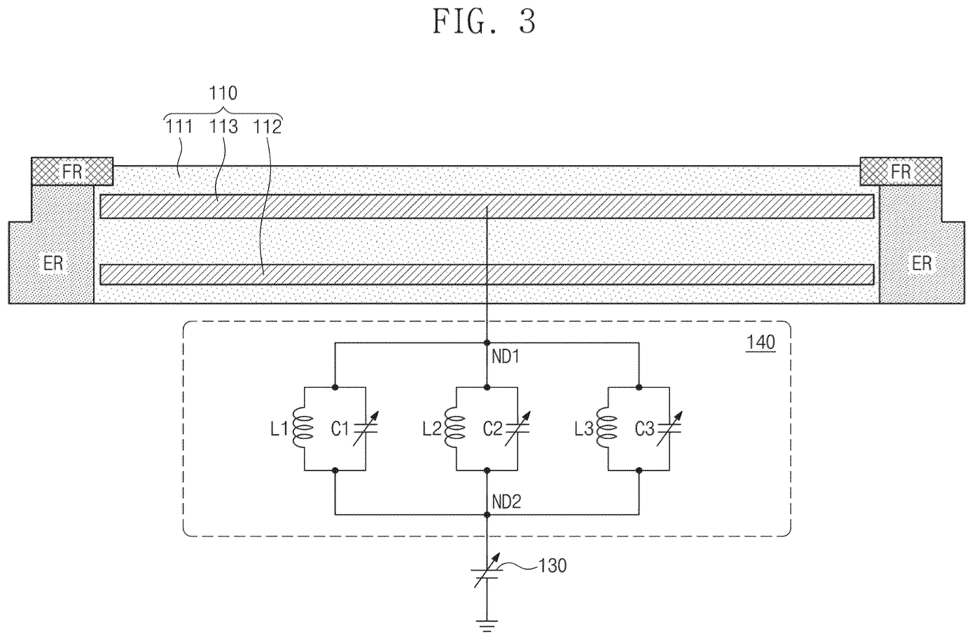

FIG. 3 is a view illustrating the variable impedance element 140 and the second power source 130 connected to the chuck electrode 113 according to some example embodiments. Referring to FIG. 3, the variable impedance element 140 and the second power source 230 that are connected to the chuck electrode 113 are illustrated. The second power source 130, the variable impedance element 140, and the chuck body 111, the plasma electrode 112, and the chuck electrode 113 of the electrostatic chuck 110 of FIG. 3 correspond to the second power source 130, the variable impedance element 140, and the chuck body 111, the plasma electrode 112, and the chuck electrode 113 of the electrostatic chuck 110 of FIG. 1.

The second power source 130 may be a variable direct current power source. The second power source 130 may generate variable direct current power based on the second control signal received from the controller 150 of FIG. 1. The second power source 130 may be connected between a ground node and a second node ND2.

The variable impedance element 140 may be connected between a first node ND1 and the second node ND2. The first node ND1 may be connected with the chuck electrode 113. The variable impedance element 140 may include at least one variable capacitor.

For example, the variable impedance element 140 may include three assemblies that are connected in parallel between the first node ND1 and the second node ND2. Each of the assemblies may include a variable impedance element and an inductor connected in parallel. Specifically, a first assembly may include a first inductor L1 and a first variable capacitor C1 connected in parallel between the first node ND1 and the second node ND2. A second assembly may include a second inductor L2 and a second variable capacitor C2 connected in parallel between the first node ND1 and the second node ND2. A third assembly may include a third inductor L3 and a third variable capacitor C3 connected in parallel between the first node ND1 and the second node ND2.

The first to third variable capacitors C1 to C3 may have capacitance values determined based on the first control signal CS1 provided from the controller 150 of FIG. 1. Accordingly, the controller 150 may control the second power source 130 and the variable impedance element 140 to control the pass characteristics of at least one harmonic wave among the plurality of harmonic waves described above. For example, the variable impedance element 140 may include at least one filter circuit configured such that a target harmonic wave having a target frequency among the plurality of harmonic waves does not pass through the electrode. In another example, the variable impedance element 140 may include a plurality of filter circuits that are able to independently control the pass characteristics of the plurality of harmonic waves, respectively, through the controller 150. The filter circuit may include at least one variable capacitor, and the capacitance of the variable capacitor may be controlled by the controller 150.

Although the variable impedance element 140 including the three variable capacitors and the three inductors is illustrated for convenience of description, example embodiments are not limited thereto, and the number of variable capacitors, the number of inductors, and a connection relationship between components may vary depending on the design.

In some example embodiments, the controller 150 may perform control such that the impedance value of the variable impedance element 140 with respect to the chuck electrode 113 is equal to the impedance value of the variable impedance element 140 with respect to the focus ring FR and may remove (or, reduce) a reflected wave caused by a harmonic wave at the edge portion of the electrostatic chuck 110.

For example, the variable impedance element 140 may include a variable capacitor connected between the chuck electrode 113 and the focus ring FR. The controller 150 may adjust the ratio between the impedance values of the chuck electrode 113 and the focus ring FR by adjusting the capacitance value of at least one variable capacitor of the variable impedance element 140.

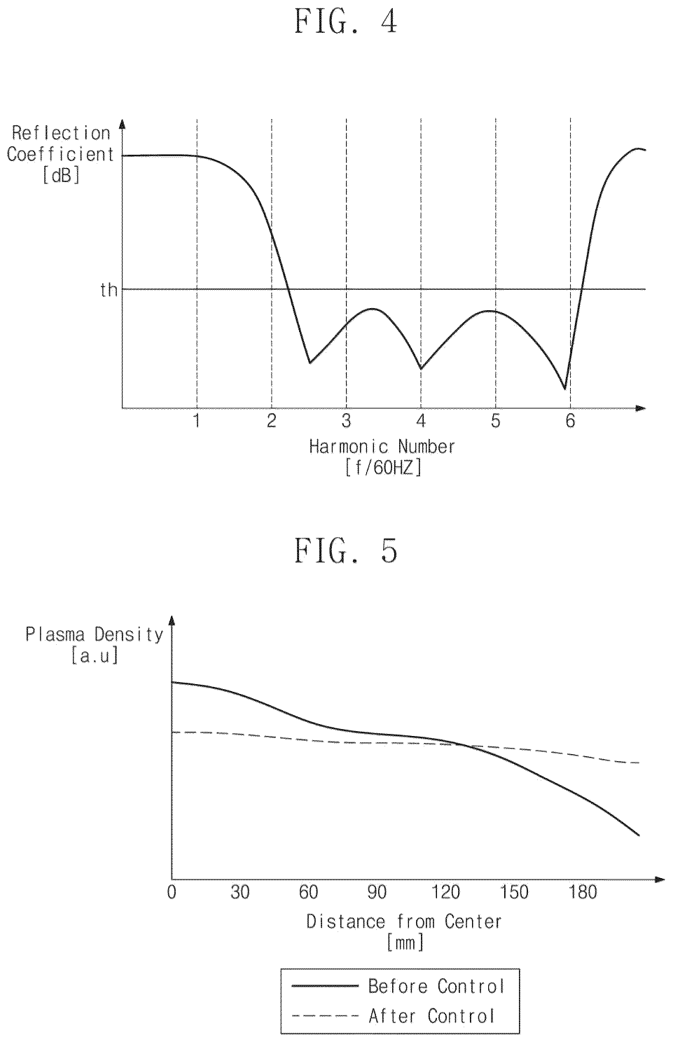

FIG. 4 is a graph depicting reflection coefficients versus harmonic numbers according to some example embodiments. Referring to FIG. 4, reflection coefficients of a plurality of harmonic waves are illustrated.

For convenience of description, results obtained by controlling third to sixth harmonic waves affecting plasma concentration by the controller 150 of FIG. 1 will be described below. However, example embodiments are not limited thereto.

The horizontal axis represents the harmonic number, and the vertical axis represents the reflection coefficient. The reflection coefficient, which is the ratio of incident voltage to reflected voltage, may represent the amount of reflection caused by an impedance difference at any connection terminal. The incident voltage may indicate the voltage of a harmonic wave, and the reflected voltage may indicate the voltage of a reflected wave obtained by reflection of the harmonic wave.

The reflection coefficients of the third to sixth harmonic waves may be lower than a threshold value (th). In this regard, the third to sixth harmonic waves may hardly be reflected at the edge portion of the electrostatic chuck 110. Accordingly, a reflected wave and a standing wave caused by the third to sixth harmonic waves may not be formed over the substrate.

FIG. 5 is a graph depicting a plasma concentration on a substrate depending on the distance from the center of the substrate according to some example embodiments. Referring to FIG. 5, the plasma concentration on the substrate depending on the distance from the center of the substrate is illustrated.

The horizontal axis represents the distance from the center of the substrate, and the vertical axis represents the plasma concentration.

The plasma concentration graph before the controller 150 of FIG. 1 controls the third to sixth harmonic waves as illustrated in FIG. 4 is illustrated by a solid line, and the plasma concentration graph after the controller 150 of FIG. 1 controls the third to sixth harmonic waves is illustrated by a dotted line.

After the controller 150 controls the third to sixth harmonic waves affecting the plasma concentration on the substrate, the plasma concentration on the substrate may be flattened. That is, the process variation of the substrate may be flattened.

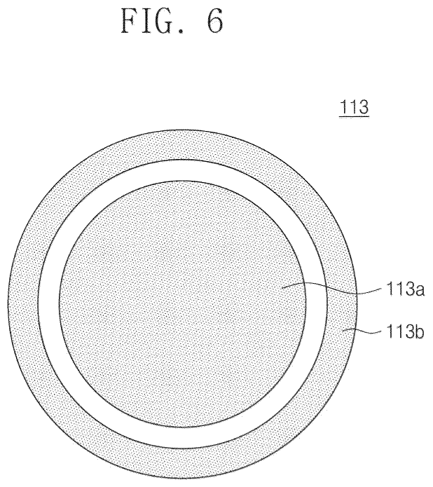

FIG. 6 is a view illustrating the chuck electrode 113 divided into two chuck electrodes according to some example embodiments. Referring to FIG. 6, the chuck electrode 113 of FIG. 1 is illustrated as being divided into two chuck electrodes. The chuck electrode 113 may include a first chuck electrode 113a and a second chuck electrode 113b.

For convenience of description, it will be exemplified that the chuck electrode 113 of FIG. 1 has a disk shape.

The first chuck electrode 113a and the second chuck electrode 113b may be located side by side over the plasma electrode 112 of FIG. 1. The first chuck electrode 113a and the second chuck electrode 113b may have the same electrical properties as the chuck electrode 113 before the division of the chuck electrode 113 into the first chuck electrode 113a and the second chuck electrode 113b.

The first chuck electrode 113a may have a disk shape smaller than that of the chuck electrode 113 before the division, and the center of the first chuck electrode 113a may coincide with the center of the chuck electrode 113. The second chuck electrode 113b may have a ring shape surrounding the first chuck electrode 113a.

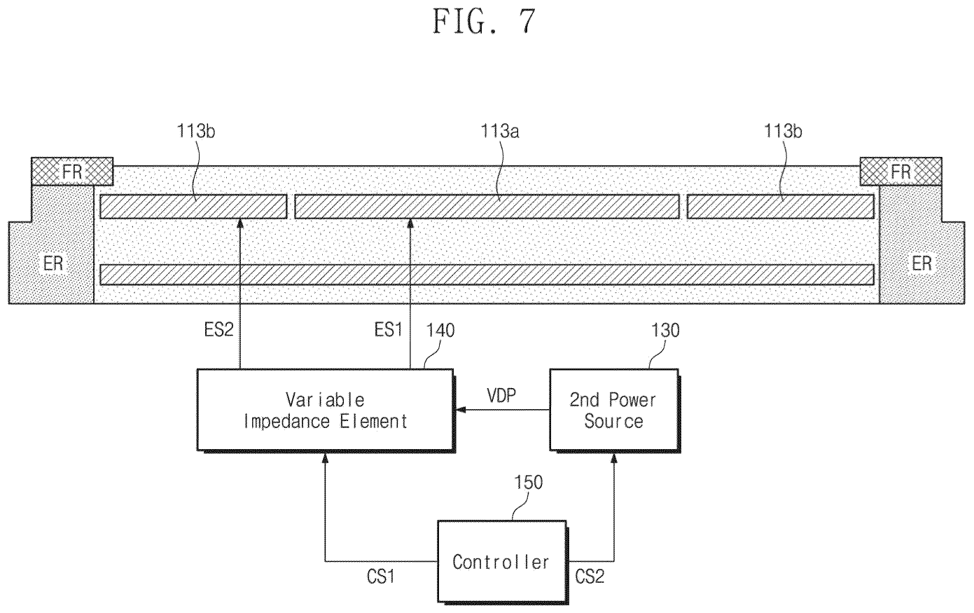

FIG. 7 is a view illustrating the substrate processing device including the chuck electrode 113 of FIG. 6. Referring to FIG. 7, the substrate processing device including the chuck electrode 113 of FIG. 6 is illustrated. The first chuck electrode 113a and the second chuck electrode 113b of FIG. 7 correspond to the first chuck electrode 113a and the second chuck electrode 113b of FIG. 6, respectively. The second power source 130, the variable impedance element 140, the controller 150, the edge ring ER, and the focus ring FR of FIG. 7 correspond to the second power source 130, the variable impedance element 140, the controller 150, the edge ring ER, and the focus ring FR of FIG. 1, respectively.

The controller 150 may provide the first control signal CS1 and the second control signal CS2 to the variable impedance element 140 and the second power source 130, respectively. The second power source 130 may provide the variable direct current power VDP to the variable impedance element 140.

The variable impedance element 140 may provide a first electrical signal ES1 and a second electrical signal ES2 to the first chuck electrode 113a and the second chuck electrode 113b, respectively, based on the variable direct current power VDP.

The controller 150 may adjust a first impedance value of the variable impedance element 140 with respect to the first chuck electrode 113a and a second impedance value of the variable impedance element 140 with respect to the second chuck electrode 113b. The first impedance value may indicate the magnitude of impedance viewed from the first chuck electrode 113a toward the variable impedance element 140. The second impedance value may indicate the magnitude of impedance viewed from the second chuck electrode 113b toward the variable impedance element 140.

The controller may control the first standing wave SW1 by adjusting at least one of the magnitude of the variable direct current power VDP, the first impedance value, and the second impedance value when the first standing wave SW1 of FIG. 2 is formed over the electrostatic chuck 110.

Specifically, referring to FIGS. 2 and 7, the first anti-node A1 of the first standing wave SW1 may be located over the first chuck electrode 113a, and the first node N1 and the second node N2 of the first standing wave SW1 may be located over the second chuck electrode 113b. In this case, the controller 150 may adjust the impedance values such that the first impedance value is smaller than the second impedance value. Accordingly, the magnitude of voltage over the first chuck electrode 113a (e.g., the electrode over which the anti-node of the first standing wave SW1 is located) may be smaller than the magnitude of voltage over the second chuck electrode 113b (e.g., the electrode over which the nodes of the first standing wave SW1 are located), and thus a plasma concentration difference due to the first standing wave SW1 may be reduced.

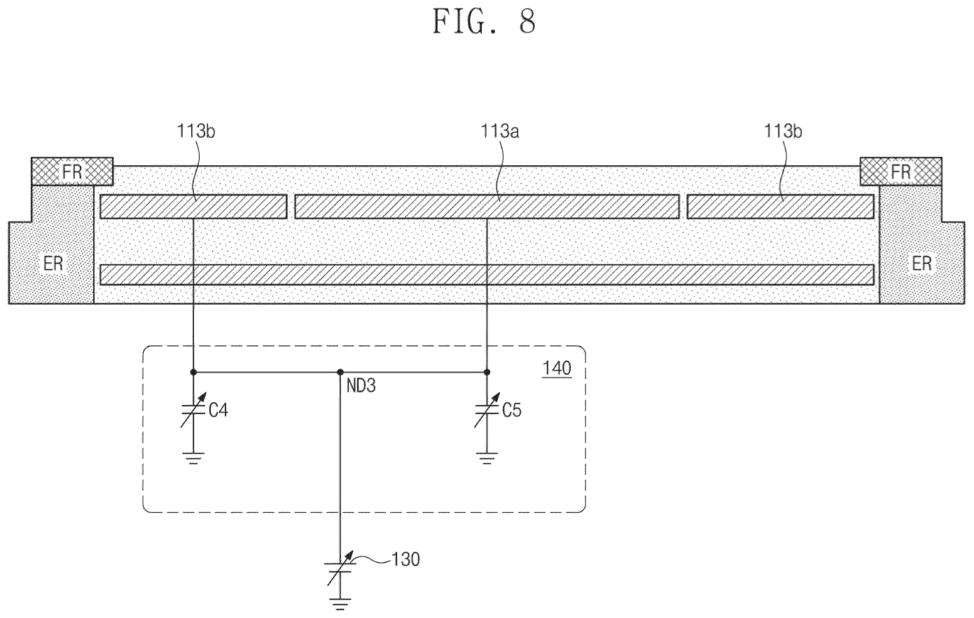

FIG. 8 is a view illustrating the second power source 130 and the variable impedance element 140 of FIG. 6. Referring to FIG. 8, the variable impedance element 140 connected to the second power source 130, the first chuck electrode 113a, and the second chuck electrode 113b is illustrated. The first chuck electrode 113a and the second chuck electrode 113b of FIG. 8 correspond to the first chuck electrode 113a and the second chuck electrode 113b of FIG. 6, respectively. The second power source 130, the variable impedance element 140, the controller 150, the edge ring ER, and the focus ring FR of FIG. 8 correspond to the second power source 130, the variable impedance element 140, the controller 150, the edge ring ER, and the focus ring FR of FIG. 1, respectively.

The second power source 130 may be a variable direct current power source. The second power source 130 may generate variable direct current power under the control of the controller 150. The second power source 130 may be connected between a third node ND3 and a ground node.

The variable impedance element 140 may include a fourth variable capacitor C4 and a fifth variable capacitor C5. The fourth variable capacitor C4 may be connected between the third node ND3 connected with the second chuck electrode 113b and the ground node. The fifth variable capacitor C5 may be connected between the third node ND3 connected with the first chuck electrode 113a and the ground node.

The capacitance values of the fourth variable capacitor C4 and the fifth variable capacitor C5 may be determined under the control of the controller 150 of FIG. 7.

The controller 150 may adjust the second impedance value and the first impedance value by adjusting the capacitance values of the fourth variable capacitor C4 and the fifth variable capacitor C5. The first impedance value may indicate the impedance value viewed from the first chuck electrode 113a toward the variable impedance element 140. The second impedance value may indicate the impedance value viewed from the second chuck electrode 113b toward the variable impedance element 140.

In some example embodiments, the controller 150 may adjust the first impedance value and the second impedance value such that the first impedance value is smaller than the second impedance value.

For convenience of description, the variable impedance element 140 including the two variable capacitors that are connected to the first chuck electrode 113a and the second chuck electrode 113b, respectively, has been described above. However, example embodiments are not limited thereto.

In some example embodiments, the variable impedance element 140 may include at least one combination in which an inductor and a variable capacitor connected in parallel and an inductor and a variable capacitor connected in series are implemented in an independent shunt form.

In some example embodiments, the controller 150 may adjust the ratio between the first impedance value and the second impedance value. Specifically, the variable impedance element 140 may include at least one component in which one variable capacitor connected between the first chuck electrode 113a and the second chuck electrode 113b, an inductor and a variable capacitor connected in parallel, or an inductor and a variable capacitor connected in series are implemented in a series form.

In some example embodiments, the variable impedance element 140 may include at least one filter circuit. The filter circuit may pass only a signal having a frequency in a specific band. For example, the filter circuit may include at least one variable capacitor and at least one inductor. However, example embodiments are not limited thereto.

In some example embodiments, the variable impedance element 140 may include at least one combination of two variable capacitors that are implemented in series and in a shunt form. For example, a sixth variable capacitor may be connected between a fourth node and a ground power source, and a seventh variable capacitor may be connected between the fourth node and a fifth node. The fourth node and the fifth node may be connected to the first chuck electrode 113a and the second chuck electrode 113b, respectively.

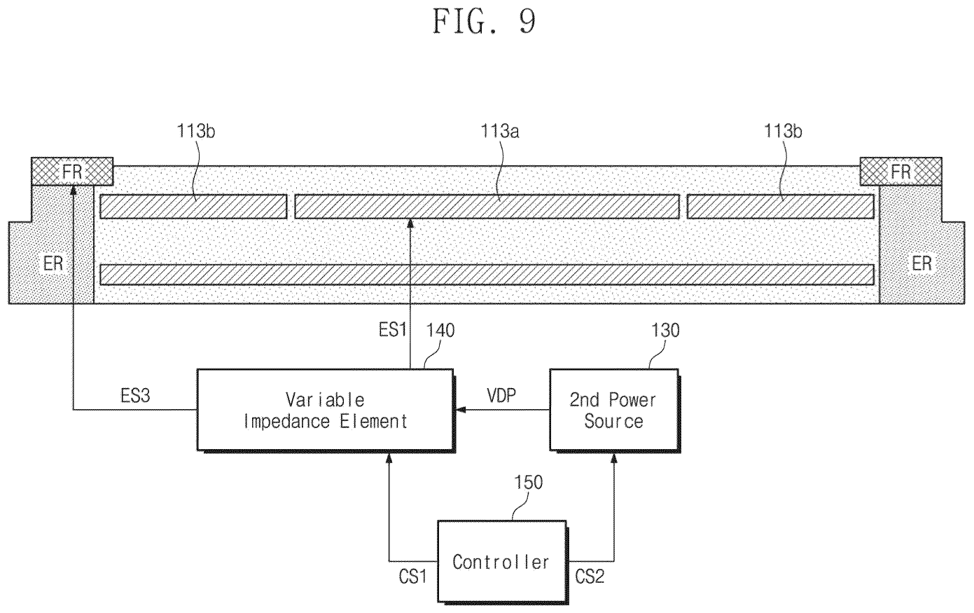

FIG. 9 is a view illustrating the substrate processing device including the chuck electrode 113 of FIG. 6. Referring to FIG. 9, the substrate processing device including the chuck electrode 113 of FIG. 6 is illustrated. The first chuck electrode 113a and the second chuck electrode 113b of FIG. 9 correspond to the first chuck electrode 113a and the second chuck electrode 113b of FIG. 6, respectively. The second power source 130, the variable impedance element 140, the controller 150, the edge ring ER, and the focus ring FR of FIG. 9 correspond to the second power source 130, the variable impedance element 140, the controller 150, the edge ring ER, and the focus ring FR of FIG. 1, respectively.

For convenience of description, repetitive descriptions identical to ones given with reference to FIG. 7 will be omitted.

Unlike that illustrated in FIG. 7, the variable impedance element 140 may be connected to the focus ring FR instead of the second chuck electrode 113b. For example, the variable impedance element 140 may be connected to the first chuck electrode 113a, the focus ring FR, and the second power source 130. The variable impedance element 140 may provide a first electrical signal ES1 and a third electrical signal ES3 to the first chuck electrode 113a and the focus ring FR, respectively, based on the variable direct current power VDP.

The controller 150 may adjust the ratio between a first impedance value and a third impedance value. The first impedance value may indicate the impedance value of the variable impedance element 140 with respect to the first chuck electrode 113a. The third impedance value may indicate the impedance value of the variable impedance element 140 with respect to the focus ring FR.

In some example embodiments, the variable impedance element 140 may be implemented as a combination of FIGS. 8 and 9. The variable impedance element 140 may provide the first electrical signal ES1, the second electrical signal (e.g., the second electrical signal ES2 of FIG. 8), and the third electrical signal ES3 to the first chuck electrode 113a, the second chuck electrode 113b, and the focus ring FR, respectively, based on the variable direct current power VDP. In this case, the controller 150 may adjust the ratio between the first impedance value and the third impedance value, and may additionally adjust the second impedance value.

For convenience of description, it has been described that the variable impedance element 140 is connected to the focus ring FR. However, example embodiments are not limited thereto. The variable impedance element 140 may be connected to another component in the processing chamber, such as the edge ring ER, instead of the focus ring FR. Alternatively, the variable impedance element 140 may be connected to the second chuck electrode 113b rather than the first chuck electrode 113a. In this case, according to some example embodiments, the controller 150 may perform control such that the ratio between the second impedance value and the third impedance value approaches 1, that is, the second impedance value and the third impedance value are equal to each other. Accordingly, reflection due to a harmonic wave may be reduced at the edge portion of the electrostatic chuck, and thus a reflected wave may be removed (or, reduced).

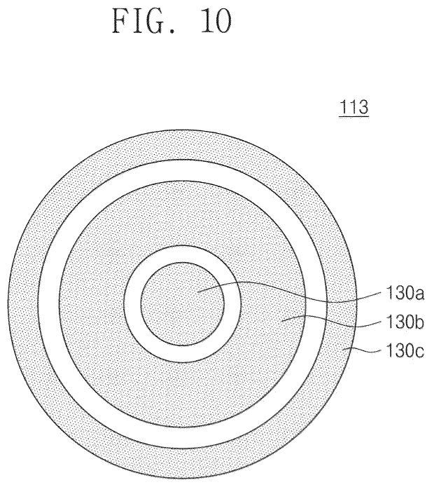

FIG. 10 is a view illustrating the chuck electrode 113 divided into three chuck electrodes according to some example embodiments. Referring to FIG. 10, the chuck electrode 113 of FIG. 1 is illustrated as being divided into three chuck electrodes. The chuck electrode 113 may include a first chuck electrode 113a, a second chuck electrode 113b, and a third chuck electrode 113c.

For convenience of description, it will be exemplified that the chuck electrode 113 of FIG. 1 has a disk shape.

The first chuck electrode 113a, the second chuck electrode 113b, and the third chuck electrode 113c may be located side by side over the plasma electrode 112 of FIG. 1. The first chuck electrode 113a, the second chuck electrode 113b, and the third chuck electrode 113c may have the same electrical properties as the chuck electrode 113 (e.g., the chuck electrode 113 of FIG. 1) before the division of the chuck electrode 113 into the first chuck electrode 113a, the second chuck electrode 113b, and the third chuck electrode 113c.

The first chuck electrode 113a may have a disk shape smaller than that of the chuck electrode 113 before the division, and the center of the first chuck electrode 113a may coincide with the center of the chuck electrode 113.

The second chuck electrode 113b may have a ring shape surrounding the first chuck electrode 113a. For example, the second chuck electrode 113b may have a shape surrounding the disk-shaped first chuck electrode 113a on the outside of the first chuck electrode 113a.

The third chuck electrode 113c may have a ring shape surrounding the second chuck electrode 113b. For example, he third chuck electrode 113c may have a larger ring shape surrounding the ring-shaped second chuck electrode 113b on the outside of the second chuck electrode 113b.

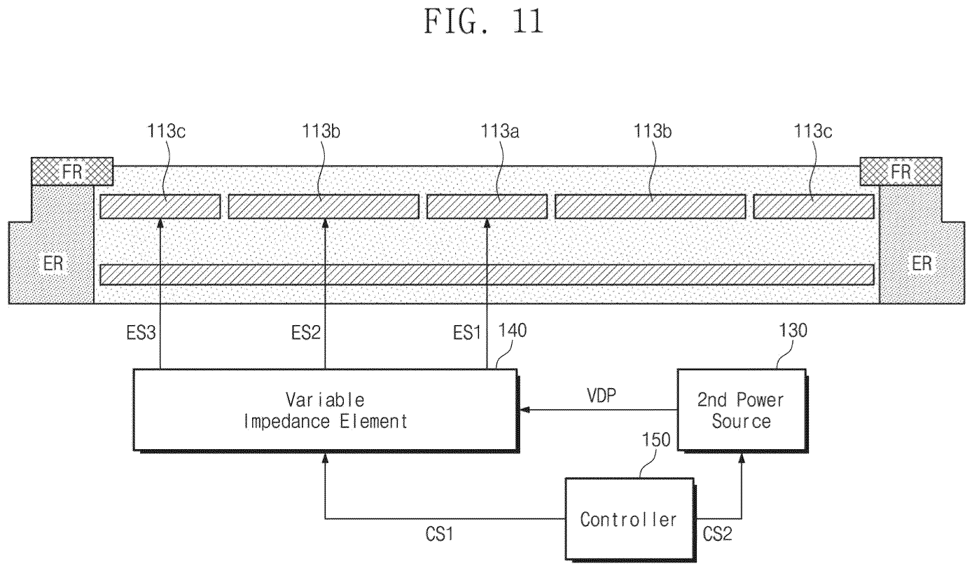

FIG. 11 is a view illustrating the substrate processing device including the chuck electrode 113 of FIG. 10. Referring to FIG. 11, the substrate processing device including the first chuck electrode 113a, the second chuck electrode 113b, and the third chuck electrode 113c of FIG. 10 is illustrated. The second power source 130, the variable impedance element 140, and the controller 150 of FIG. 11 correspond to the second power source 130, the variable impedance element 140, and the controller 150 of FIG. 1, respectively.

The second power source 130 may generate the variable direct current power VDP based on the second control signal CS2 received from the controller 150. The variable impedance element 140 may include at least one variable capacitor. The capacitance value of the variable capacitor may be determined based on the first control signal CS1 provided from the controller 150.

The variable impedance element 140 may provide the first electrical signal ES1, the second electrical signal ED2, the third electrical signal ES3 to the first chuck electrode 113a, the second chuck electrode 113b, and the third chuck electrode 113c, respectively, based on the variable direct current power VDP.

The controller 150 may adjust the first impedance value, the second impedance value, the third impedance value, and the magnitude of the variable direct current power. The first impedance value may indicate the impedance value viewed from the first chuck electrode 113a toward the variable impedance element 140. The second impedance value may indicate the impedance value viewed from the second chuck electrode 113b toward the variable impedance element 140. The third impedance value may indicate the impedance value viewed from the third chuck electrode 113c toward the variable impedance element 140.

In some example embodiments, referring to FIGS. 2 and 11, when a standing wave such as the second standing wave SW2 of FIG. 2 is formed over the electrostatic chuck, the fourth node N4 close to the central portion of the substrate among the nodes of the second standing wave SW2 may be located over the first chuck electrode 113a. The third node N3 and the fifth node N5 close to the edge portion of the substrate among the nodes of the second standing wave SW2 may be located over the third chuck electrode 113c. The anti-nodes A2 and A3 of the second standing wave SW2 may be located over the second chuck electrode 113b. The controller 150 may control the first to third impedance values such that the first impedance value and the third impedance value are greater than the second impedance value. Accordingly, the magnitudes of the voltages of the electrodes over which the nodes of the second standing wave are located may be increased, and the magnitude of the voltage of the electrode over which the anti-nodes of the second standing wave are located may be decreased. Thus, plasma concentration may be flattened.

In some example embodiments, the controller 150 may adjust the ratio between two impedance values among the first to third impedance values and may adjust the remaining impedance value.

In some example embodiments, the variable impedance element 140 may be additionally connected with another component, such as the focus ring FR, and may provide a fourth electrical signal to the focus ring FR based on the variable direct current power VDP. The controller 150 may adjust a fourth impedance value of the variable impedance element 140 with respect to the focus ring FR.

More specifically, the controller 150 may adjust each of the first to fourth impedance values, or may adjust the ratios between two impedance values among the first to fourth impedance values.

Although the substrate processing device including the chuck electrode divided into the three chuck electrodes is illustrated in FIG. 11, example embodiments are not limited thereto, and the chuck electrode may be divided into four or more chuck electrodes. In this case, the controller 150 may adjust each of the impedance values of the four chuck electrodes, or may adjust the ratios between two impedance values among the four impedance values.

According to the example embodiments, the substrate processing device including the variable impedance element is provided.

The substrate processing device adjusts the impedance of the chuck electrode using the variable impedance element between the direct current power source and the chuck electrode to remove a specific harmonic component caused by alternating current power or control a standing wave formed over the electrostatic chuck by a harmonic wave, thereby uniformly maintaining a change in plasma concentration.

While aspects of example embodiments have been particularly shown and described, it will be understood that various changes in form and details may be made therein without departing from the spirit and scope of the following claims.

What is claimed is:

1. A substrate processing device comprising:
a chamber body;
an electrostatic chuck provided in the chamber body, the electrostatic chuck comprising a plasma electrode and a first chuck electrode provided over the plasma electrode;
a first power source configured to supply alternating current power to the plasma electrode;
a second power source configured to generate variable direct current power;
a variable impedance circuit configured to provide a first electrical signal to the first chuck electrode based on the variable direct current power; and
a controller connected with the second power source and the variable impedance circuit,
wherein the controller is configured to variably adjust any one or any combination of a first impedance value of the variable impedance circuit with respect to the first chuck electrode and a magnitude of the variable direct current power to control a plurality of harmonic waves formed over the electrostatic chuck by the alternating current power.

2. The substrate processing device of claim 1, wherein the variable impedance circuit is connected between the first chuck electrode and the controller.

3. The substrate processing device of claim 1, wherein the variable impedance circuit comprises at least one filter circuit configured to block a target frequency, and
wherein the controller is further configured to variably adjust any one or any combination of the magnitude of the variable direct current power and the first impedance value, to remove a target harmonic wave having the target frequency among the plurality of harmonic waves.

4. The substrate processing device of claim 3, wherein the target frequency is N times greater than a frequency of the alternating current power, and
where N is a natural number of 2 or more.

5. The substrate processing device of claim 1, wherein the variable impedance circuit comprises at least one variable capacitor controlled by the controller.

6. The substrate processing device of claim 5, wherein the at least one variable capacitor comprises a vacuum variable capacitor (VVC).

7. The substrate processing device of claim 1, further comprising:
an edge ring surrounding the electrostatic chuck; and
a focus ring supported by the edge ring,
wherein the variable impedance circuit is further configured to provide a second electrical signal to the focus ring based on the variable direct current power, and
wherein the controller is further configured to adjust a ratio between a second impedance value of the variable impedance circuit with respect to the focus ring and the first impedance value.

8. The substrate processing device of claim 7, wherein the ratio is 1:1.

9. The substrate processing device of claim 1, wherein the electrostatic chuck further comprises a second chuck electrode adjacent the first chuck electrode over the plasma electrode,
wherein the variable impedance circuit is further configured to provide a second electrical signal to the second chuck electrode based on the variable direct current power, and
wherein the controller is further configured to adjust any one or any combination of a second impedance value of the variable impedance circuit with respect to the second chuck electrode, the magnitude of the variable direct current power, and the first impedance value.

10. The substrate processing device of claim 9, wherein the first chuck electrode has a disk shape, and the second chuck electrode has a ring shape surrounding the first chuck electrode.

11. The substrate processing device of claim 10, wherein the controller is further configured to the first impedance value and the second impedance value such that the first impedance value is less than the second impedance value,
wherein an anti-node of a standing wave formed over the electrostatic chuck by the plurality of harmonic waves is located over the first chuck electrode, and
wherein a node of the standing wave is located over the second chuck electrode.

12. The substrate processing device of claim 9, wherein the controller is further configured to adjust a ratio between the first impedance value and the second impedance value.

13. The substrate processing device of claim 9, further comprising:
an edge ring surrounding the electrostatic chuck; and
a focus ring supported by the edge ring,
wherein the variable impedance circuit is further configured to provide a third electrical signal to the focus ring based on the variable direct current power, and
wherein the controller is further configured to adjust a ratio between a third impedance value of the variable impedance circuit with respect to the focus ring and the first impedance value.

14. The substrate processing device of claim 9, wherein the electrostatic chuck further comprises a third chuck electrode adjacent the first chuck electrode and the second chuck electrode over the plasma electrode,
wherein the variable impedance circuit is further configured to provide a third electrical signal to the third chuck electrode based on the variable direct current power, and
wherein the controller is further configured to adjust any one or any combination of a third impedance value of the variable impedance circuit with respect to the third chuck electrode, the magnitude of the variable direct current power, the first impedance value, and the second impedance value.

15. The substrate processing device of claim 14, wherein the first chuck electrode has a disk shape, the second chuck electrode has a ring shape surrounding the first chuck electrode, and the third chuck electrode has a ring shape surrounding the second chuck electrode.

16. The substrate processing device of claim 15, wherein the controller is further configured to adjust any one or any combination of the first impedance value, the second impedance value, and the third impedance value such that the second impedance value is less than the first impedance value and less than the third impedance value,
wherein a standing wave formed over the electrostatic chuck by the plurality of harmonic waves comprises a first node, a second node, a third node, a first anti-node, and a second anti-node,
wherein the first node close overlaps a center of the first chuck electrode,
wherein the first anti-node and the second anti-node overlap the second chuck electrode, and
wherein the second node and the third node overlap the third chuck electrode.

17. The substrate processing device of claim 14, wherein the controller is further configured to adjust the third impedance value and a ratio between the first impedance value and the second impedance value.

18. The substrate processing device of claim 14, further comprising:
an edge ring configured surrounding the electrostatic chuck; and
a focus ring supported by the edge ring,
wherein the variable impedance circuit is further configured to provide a fourth electrical signal to the focus ring based on the variable direct current power, and
wherein the controller is further configured to adjust a ratio between a fourth impedance value of the variable impedance circuit with respect to the focus ring and the first impedance value.

19. A substrate processing device comprising:
a chamber body;
an electrostatic chuck provided in the chamber body, the electrostatic chuck comprising a plasma electrode, a first chuck electrode provided over the plasma electrode and a second chuck electrode adjacent the first chuck electrode;
a first power source configured to supply alternating current power to the plasma electrode;
a second power source configured to generate variable direct current power;
a variable impedance circuit configured to, based on the variable direct current power, provide a first electrical signal to the first chuck electrode and a second electrical signal to the second chuck electrode; and
a controller connected with the second power source and the variable impedance circuit,
wherein the controller is configured to variably adjust a magnitude of the variable direct current power and a ratio between a first impedance value of the variable impedance circuit with respect to the first chuck electrode and a second impedance value of the variable impedance circuit with respect to the second chuck electrode to control a plurality of harmonic waves formed over the electrostatic chuck by the alternating current power.

20. A substrate processing device comprising:
a chamber body;
an electrostatic chuck provided in the chamber body, the electrostatic chuck comprising a plasma electrode, a first chuck electrode provided over the plasma electrode, a second chuck electrode surrounding the first chuck electrode and a third chuck electrode surrounding the second chuck electrode;
a first power source configured to supply alternating current power to the plasma electrode;
a second power source configured to generate variable direct current power;
a variable impedance circuit configured to provide a first electrical signal, a second electrical signal, and a third electrical signal to the first chuck electrode, the second chuck electrode and the third chuck electrode, respectively, based on the variable direct current power; and
a controller connected with the second power source and the variable impedance circuit,
wherein the controller is configured to variably adjust a first impedance value of the variable impedance circuit with respect to the first chuck electrode, a second impedance value of the variable impedance circuit with respect to the second chuck electrode, a third impedance value of the variable impedance circuit with respect to the third chuck electrode, and a magnitude of the variable direct current power to control a plurality of harmonic waves formed over the electrostatic chuck by the alternating current power.
